(19) United States
(12) Patent Application Publication
(10) Pub. No.: US 2025/0067820 A1
(43) Pub. Date: Feb. 27, 2025

(54) SYSTEM AND METHOD FOR MONITORING AGING STATE OF POWER CABLE

(71) Applicant: KOREA HYDRO & NUCLEAR POWER CO., LTD., Gyeongju-si, Gyeongsangbuk-do (KR)

(72) Inventors: Kyungheum PARK, Daejeon (KR); Kyungnam JANG, Daejeon (KR); Chang-Keun YANG, Daejeon (KR)

(73) Assignee: KOREA HYDRO & NUCLEAR POWER CO., LTD., Gyeongju-si, Gyeongsangbuk-do (KR)

(21) Appl. No.: 18/723,171

(22) PCT Filed: May 12, 2023
(86) PCT No.: PCT/KR2023/006513

§ 371 Date: Jun. 21, 2024

(30) Foreign Application Priority Data
May 16, 2022 (KR) 10-2022-0059498

(51) Int. Cl. G01R 31/58

(52) U.S. Cl. CPC G01R 31/58

(57) ABSTRACT

The present invention relates to a system and method for monitoring the aging state of a power cable, in which a measuring unit measures the elongation at break of at least one power cable, a data generation unit generates a relational expression on the basis of the elongation at break of each of a heated cable, to which voltage has been applied to raise the temperature thereof, and a non-heated cable, to which no voltage has been applied, from among the measured cables, and an aging state derivation unit derives the aging state of a target power cable by calculating the elongation at break of the target power cable, of which the aging state is to be monitored, by using the relational expression. Accordingly, it is possible to verify the aging state of a power cable quickly and efficiently and to improve the credibility of the aging state of the power cable.

### TECHNICAL FIELD

The present disclosure relates to a system and a method for monitoring the age state of a cable, and to a technology that considers self-heating of a power cable to monitor the age state of the cable.

### BACKGROUND ART

Power cables are used to transmit power from power plants to homes and buildings, and aging evaluation thereof is required to be performed periodically to minimize power loss due to resistance depending on the age states of the cables.

Cable deposit is used as a method of cable aging condition monitoring to predict and evaluate the aging condition of cables.

Cable deposit is a method of placing a cable specimen at the same location as a cable whose condition is to be monitored, making the cable specimen to be in the same condition as an actual aging condition of a cable in the field, recovering the specimen after a predetermined period of time, and measuring an aging condition thereof in a laboratory.

However, monitoring an aging condition by cable deposit does not consider an Ohm heating effect caused by cable resistance generated in power cables, etc., so there is a problem in that measurement results are unreliable.

To solve this problem, a method for monitoring the aging condition of a cable that considers self-heating thereof due to resistance of the cable is proposed.

### Document of Related Art

[Patent Document] Korean Patent No. 10-0880440 (2009.01.29)

### DISCLOSURE

### Technical Problem

The present disclosure may provide a system and a method for monitoring the age state of a cable, in which an age state due to self-heating is able to be monitored by power applied to a power cable.

### Technical Solution

According to an aspect of the present disclosure, a system for monitoring an age state of a power cable includes a measuring unit configured to measure elongation at break of at least one power cable, a data generation unit configured to generate a relational expression by using elongation at break of each of a heated cable to which a voltage is applied to raise a temperature thereof and a non-heated cable to which no voltage is applied, among the measured power cables, and an age state derivation unit configured to derive an age state of a target power cable by calculating elongation at break of the target power cable whose age state is to be monitored by using the relational expression.

Preferably, the target power cable may be a non-heated cable exposed for a predetermined period of time to a location adjacent to a power cable to which a voltage is applied.

Preferably, the data generation unit may generate a graph showing a change in an age state over time by using the elongation at break of each of the heated cable and the non-heated cable.

Preferably, the age state derivation unit may derive an aging rate according to a temperature of the heated cable and a temperature of the non-heated cable.

Preferably, the age state derivation unit may derive elongation at break of a non-heated cable corresponding to the elongation at break of the target power cable and calculate the derived elongation at break of the non-heated cable by using the relational expression to derive elongation at break of a heated cable.

Preferably, the heated cable may be a power cable with a temperature of 70° C. to 110° C., and the non-heated cable may be a power cable with a temperature of 20° C. to 60° C.

Preferably, the age state may be derived in any one unit of seconds, minutes, hours, days, months, and years.

According to another aspect of the present disclosure, a method for monitoring the age state of a power cable includes measuring, by a measuring unit, elongation at break of at least one power cable, generating data by a data generation unit generating a relational expression by using elongation at break of each of a heated cable to which a voltage is applied to raise a temperature thereof and a non-heated cable to which no voltage is applied, among the measured power cables, and deriving, by an age state derivation unit, an age state of a target power cable by calculating elongation at break of the target power cable whose age state is to be monitored by using the relational expression.

### Advantageous Effects

According to the present disclosure, it is possible to verify the age state of a power cable quickly and efficiently, and to improve the reliability of the age state of the power cable.

### DESCRIPTION OF DRAWINGS

FIG. 1 is a configuration diagram of the system for monitoring the age state of a power cable according to an embodiment.

FIG. 2 is a graph illustrating the age state of each of a heated cable and a non-heated cable according to an embodiment.

FIG. 3 is a flowchart illustrating a method for monitoring the age state of a power cable according to an embodiment.

### BEST MODE

Hereinafter, a system and a method for monitoring the age state of a cable according to the present disclosure will be described in detail with reference to the accompanying drawings. In this process, the thickness of lines or sizes of components shown in the drawings may be exaggerated for clarity and convenience of explanation. In addition, terms to be described below are terms defined in consideration of functions in the present disclosure, and may vary depending on an operator's intention or practice. Therefore, definitions of these terms should be made on the basis of contents throughout this specification.

The purpose and effect of the present disclosure may be naturally understood or made clearer by the description below, and the purpose and effect of the present disclosure are not limited to the description below. Additionally, when explaining the present disclosure, when it is determined that a detailed description of the publicly known technology related to the present disclosure may unnecessarily obscure the gist of the present disclosure, detailed description thereof will be omitted.

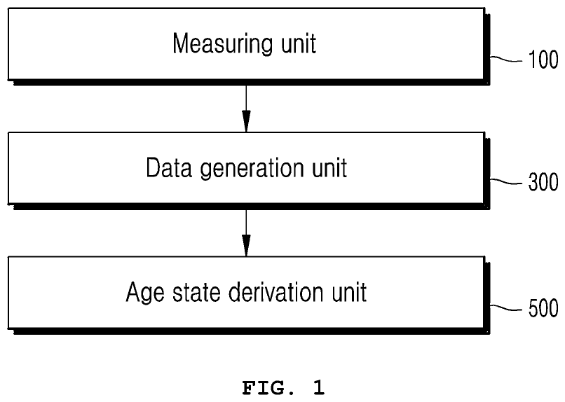

FIG. 1 is a configuration diagram of the system for monitoring the age state of a power cable according to an embodiment.

As illustrated in FIG. 1, the system for monitoring the age state of a power cable according to the embodiment may include a measuring unit 100, a data generation unit 300, and an age state derivation unit 500.

The measuring unit 100 measures the elongation at break of at least one power cable.

The data generation unit 300 generates a relational expression by using the elongation at break of each of a heated cable to which a voltage is applied to raise a temperature thereof and a non-heated cable to which no voltage is applied among the measured power cables.

Here, the data generation unit 300 may generate a graph showing a change in an age state over time by using the elongation at break of each of the heated cable and the non-heated cable.

The age state derivation unit 500 derives the age state of a target power cable by calculating the elongation at break of the target power cable whose age state is to be monitored by using the relational expression.

Here, the target power cable may be a non-heated cable exposed for a predetermined period of time to a location adjacent to a power cable to which a voltage is applied.

In addition, the age state derivation unit 500 may derive an aging rate according to the temperature of the heated cable and the temperature of the non-heated cable.

The age state derivation unit 500 may derive the elongation at break 10 of the non-heated cable corresponding to the elongation at break of the target power cable, and may calculate the derived elongation at break 10 of the non-heated cable by using the relational expression to derive the elongation at break 20 of the heated cable.

In this case, the heated cable may be a power cable with a temperature of 70° C. to 110° C., and the non-heated cable may be a power cable with a temperature of 20° C. to 60° C.

The age state may be derived in any one unit of seconds, minutes, hours, days, months, and years.

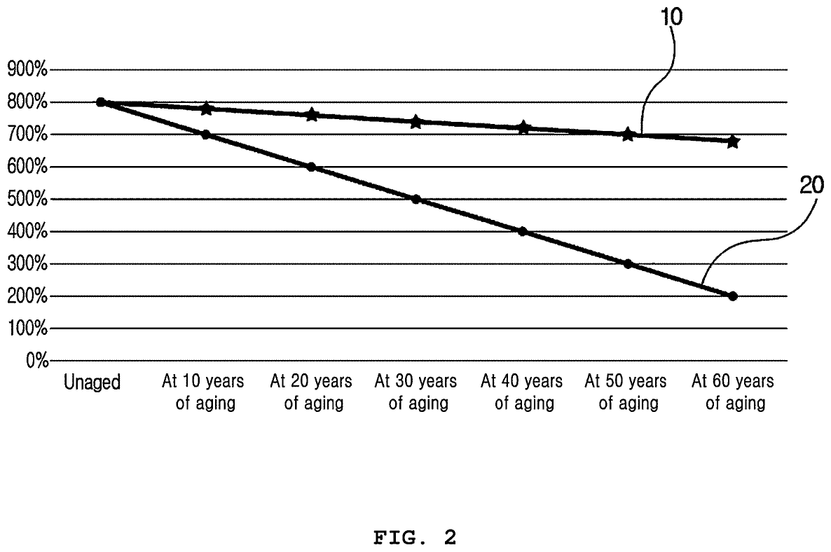

FIG. 2 is a graph illustrating the age state of each of a heated cable and a non-heated cable according to an embodiment.

As illustrated in FIG. 2, the age state of each of the heated cable and the non-heated cable according to an embodiment may be derived by measuring the elongation at break (EAB) of each power cable. Here, the elongation at break over time may be derived for each temperature of the power cable. That is, among power cables, when comparing the elongation at break 20 of the heated cable having a temperature increased due to the application of power, and the elongation at break 10 of the non-heated cable to which no power is applied, the elongation at break 20 of the heated cable having the temperature increased due to the application of power decreases rapidly over time, compared to the elongation at break 10 of the non-heated cable to which no power is applied.

The rapid decrease of the elongation at break 20 of the heated cable indicates that as a temperature thereof increases, an aging rate thereof increases, and it is possible to more precisely observe the age state of a power cable whose age state is to be monitored by considering heating caused by the application of power.

In this case, the temperature of the power cable may be 70° C. to 110° C. for the heated cable and 20° C. to 60° C. for the non-heated cable. More preferably, the heated cable may be assumed to have 90° C., and the non-heated cable may be assumed to have 40° C. to be shown in [Table 1], but the cables are not limited thereto, and the temperature of the heated cable may vary depending on the amount of power applied to each power cable.

TABLE 1

| | | At 10 | At 20 | At 30 | At 40 | At 50 | At 60 |
|---|---|---|---|---|---|---|---|
| | | years | years | years | years | years | years |
| | | of | of | of | of | of | of |
| EAB | Unaged | aging | aging | aging | aging | aging | aging |
| Heated | 800% | 700% | 600% | 500% | 400% | 300% | 200% |
| cable (90° C.) | | | | | | | |
| Non-heated | 800% | 780% | 760% | 740% | 720% | 700% | 680% |
| cable (40° C.) | | | | | | | |

Here, the elongation at break for each test cycle of the heated cable and the non-heated cable may be derived from Arrhenius equation, and the Arrhenius equation may be expressed as the following equation.

$$k = A {e}^{- \frac{{E}_{a}}{R T}} \qquad [ Equation 1 ]$$

In Equation 1, k is a rate constant, T is an absolute temperature, A is an Arrhenius constant, Ea is activation energy, and R is a gas constant. That is, the more frequent collisions, the lower activation energy, and the higher a temperature, the more a reaction rate increases, and when the reaction rate increases, an aging rate becomes faster.

That is, when it is intended to monitor the age state of a power cable to which power has been applied for a long time, the age state thereof may be derived by measuring the elongation at break of a target power cable which is arranged at a location adjacent to the power cable whose age state is to be monitored and is exposed thereto for a predetermined period. In this case, since the target power cable is a non-heated cable to which power is not applied, the elongation at break 10 of the non-heated cable of 40° C. may be derived.

When the elongation at break 10 of the non-heated cable of 40° C. is 790%, the elongation at break 20 of the heated cable may be derived as 750% by being calculated from the relational expression, and the elongation at break 10 of the non-heated cable of 90° C. may be determined to have aged for about 5 years.

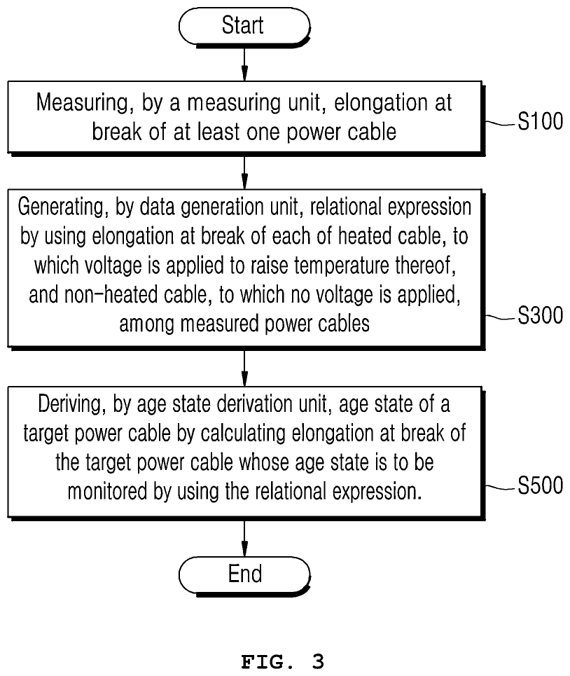

FIG. 3 is a flowchart illustrating the method for monitoring the age state of a power cable according to an embodiment.

As illustrated in FIG. 3, the method for monitoring the age state of a power cable according to an embodiment may include measuring at S100, generating data at S300, and deriving an age state at S500.

In the measuring at S100, the measuring unit 100 measures the elongation at break of at least one power cable.

In the generating of data at S300, the data generation unit 300 generates the relational expression by using the elongation at break of each of the heated cable to which a voltage is applied to raise a temperature thereof and the non-heated cable to which no voltage is applied among the measured power cables.

Here, in the generating of data at S300, by using the elongation at break measured from each of the heated cable and the non-heated cable, a graph showing a change in an age state over time may be generated.

In the deriving of an age state at S500, the age state derivation unit 500 calculates the elongation at break of the target power cable whose age state is to be monitored by using the relational expression and derives the age state of the target power cable.

Here, in the deriving of an age state at S500, the elongation at break 10 of the non-heated cable corresponding to the elongation at break of the target power cable may be derived, and the derived elongation at break 10 of the non-heated cable may be calculated by using the relational expression to derive the elongation at break 20 of the heated cable.

Although the present disclosure has been described in detail through representative embodiments above, those skilled in the art will understand that various modifications may be made to the above-described embodiments without departing from the scope of the present disclosure. Therefore, the scope of rights of the present disclosure should not be limited to the described embodiments, but should be determined not only by the claims to be described later, but also by all changes or modified forms derived from concepts equivalent to the claims.

### DESCRIPTION FO THE REFERENCE NUMERALS IN THE DRAWINGS

100: Measuring unit 300: Data generation unit
500: Age state derivation unit
10: Elongation at break of a non-heated cable 20: Elongation at break of a heated cable

1. A system for monitoring an age state of a power cable, the system comprising:
a measuring unit configured to measure elongation at break of at least one power cable;
a data generation unit configured to generate a relational expression by using elongation at break of each of a heated cable to which a voltage is applied to raise a temperature thereof and a non-heated cable to which no voltage is applied, among the measured power cables; and
an age state derivation unit configured to derive an age state of a target power cable by calculating elongation at break of the target power cable whose age state is to be monitored by using the relational expression.

2. The system of claim 1, wherein the target power cable is a non-heated cable exposed for a predetermined period of time to a location adjacent to a power cable to which a voltage is applied.

3. The system of claim 1, wherein the data generation unit generates a graph showing a change in an age state over time by using the elongation at break of each of the heated cable and the non-heated cable.

4. The system of claim 1, wherein the age state derivation unit derives an aging rate according to a temperature of the heated cable and a temperature of the non-heated cable.

5. The system of claim 1, wherein the age state derivation unit derives elongation at break of a non-heated cable corresponding to the elongation at break of the target power cable and calculates the derived elongation at break of the non-heated cable by using the relational expression to derive elongation at break of a heated cable.

6. The system of claim 1, wherein the heated cable is a power cable with a temperature of 70° C. to 110° C., and the non-heated cable is a power cable with a temperature of 20° C. to 60° C.

7. The system of claim 1, wherein the age state is derived in any one unit of seconds, minutes, hours, days, months, and years.

8. A method for monitoring an age state of a power cable, the method comprising:
measuring, by a measuring unit, elongation at break of at least one power cable;
generating data by a data generation unit generating a relational expression by using elongation at break of each of a heated cable to which a voltage is applied to raise a temperature thereof and a non-heated cable to which no voltage is applied, among the measured power cables; and
deriving, by an age state derivation unit, an age state of a target power cable by calculating elongation at break of the target power cable whose age state is to be monitored by using the relational expression.
